(19) United States
(12) Patent Application Publication
(10) Pub. No.: US 2016/0013381 A1
(43) Pub. Date: Jan. 14, 2016

(54) LIGHT EMITTING DEVICE STRUCTURE

(71) Applicant: Genesis Photonics Inc., Tainan (TW)

(72) Inventors: Shao-Ying Ting, Tainan City (TW); Kuan-Chieh Huang, Tainan City (TW); Jing-En Huang, Tainan City (TW); Yi-Ru Huang, Tainan City (TW)

(21) Appl. No.: 14/542,657

(22) Filed: Nov. 17, 2014

(30) Foreign Application Priority Data
Jul. 14, 2014 (TW) 103124158

(51) Int. Cl. H01L 33/60; H01L 33/50; H01L 33/54

(52) U.S. Cl. CPC H01L 33/60; H01L 33/54; H01L 33/505

(57) ABSTRACT

A light emitting device structure includes a light emitting device, a molding compound, a transparent substrate and a reflective layer. The light emitting device has an upper surface and a lower surface opposite to each other, a side surface connecting the upper and lower surfaces, and a first pad and a second pad located on the lower surface and separated from each other. The molding compound at least encapsulates the upper surface and the side surface, and exposes the first pad and the second pad. The transparent substrate is disposed above the upper surface of the light emitting device, and the molding compound is located between the transparent substrate and the light emitting device. The reflective layer directly covers the side surface of the light emitting device, wherein the molding compound encapsulates the reflective layer and exposes a bottom surface of the reflective layer.

### CROSS-REFERENCE TO RELATED APPLICATION

This application claims the priority benefit of Taiwan application serial no. 103124158, filed on Jul. 14, 2014. The entirety of the above-mentioned patent application is hereby incorporated by reference herein and made a part of this specification.

### BACKGROUND

1. Field of the Invention

The invention relates to a light emitting device structure, and more particularly, to a light emitting device structure having a reflective layer.

2. Description of Related Art

In the conventional light emitting diode (LED) structure, the reason that a white LED structure emits a white light is because a blue LED chip is adopted to emit a blue light. The blue light is converted into a yellow light after passing through phosphors, and the yellow light converted by the phosphors is mixed with the blue light which is not converted so as to generate the white light. The blue light emitted by an LED chip has a certain level of directivity, such that the blue light deviates from an optical axis in greater angles has weaker light intensity, thereby strength of the yellow light deviating from an optical axis in greater angles is greater than strength of the blue light. Accordingly, the LED structure generates uneven colors and phenomenon of yellow and blue circles, thereby influencing optical surfaces of the LED structure.

### SUMMARY OF THE INVENTION

The invention provides a light emitting device structure, which may present preferable optical performance.

A light emitting device structure of the invention includes a light emitting device, a molding compound, a transparent substrate and a reflective layer. The light emitting device has an upper surface and a lower surface opposite to each other, a side surface connecting the upper surface and the lower surface, and a first pad and a second pad located on the lower surface and separated from each other. The molding compound at least encapsulates the upper surface and the side surface of the light emitting device, and exposes the first pad and the second pad of the light emitting device. The transparent substrate is disposed above the upper surface of the light emitting device, wherein the molding compound is located between the transparent substrate and the light emitting device. The reflective layer directly covers the side surface of the light emitting device, wherein the molding compound encapsulates the reflective layer and exposes a bottom surface of the reflective layer.

In an embodiment of the invention, the bottom surface of the reflective layer is aligned with a first bottom surface of the first pad and a second bottom surface of the second pad.

In an embodiment of the invention, a top surface of the reflective layer opposite to the bottom surface is aligned with the upper surface of the light emitting device.

In an embodiment of the invention, the molding compound is further filled in a gap between the first pad and a second pad of the light emitting device.

In an embodiment of the invention, the reflective layer further extends to be disposed on a lower bottom surface of a molding compound, and a bottom surface of the reflective layer is aligned with a first bottom surface of a first pad and a second bottom surface of a second pad.

In an embodiment of the invention, a first peripheral surface of the molding compound is aligned with a second peripheral surface of the reflective layer.

In an embodiment of the invention, the second peripheral surface of the reflective layer is aligned with a third peripheral surface of a transparent substrate.

In an embodiment of the invention, the molding compound includes a resin compound layer and a phosphor-doped compound layer. The resin compound layer encapsulates the reflective layer, and the phosphor-doped compound layer covers an upper surface of a light emitting device, a top surface of the reflective layer and an upper top surface of the resin compound layer.

In an embodiment of the invention, the molding compound includes a transparent molding compound or a phosphor-doped molding compound.

In an embodiment of the invention, the reflective layer has a reflectivity of at least greater than 50%.

In an embodiment of the invention, the reflective layer includes a silver layer, an aluminum layer or a Bragg reflection layer.

In an embodiment of the invention, the reflective layer is a reflective layer doped with a plurality of reflective particles.

In view of the foregoing, since the light emitting device structure of the invention has the reflective layer, and the reflective layer is directly disposed on the side surface of the light emitting device, a luminous flux of forward irradiation of the light emitting device may be increased, and a luminous flux of lateral irradiation thereof may be reduced. Accordingly, the light emitting device structure of the invention not only obtains preferable luminescent efficiency, but also minimizes color unevenness and phenomenon of yellow and blue circles.

Several exemplary embodiments accompanied with figures are described in detail below to further describe the invention in details.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional schematic view illustrating a light emitting device structure according to an embodiment of the invention.

FIG. 2 is a cross-sectional schematic view illustrating a light emitting device structure according to another embodiment of the invention.

FIG. 3 is a cross-sectional schematic view illustrating a light emitting device structure according to another embodiment of the invention.

FIG. 4 is a cross-sectional schematic view illustrating a light emitting device structure according to another embodiment of the invention.

### DESCRIPTION OF THE EMBODIMENTS

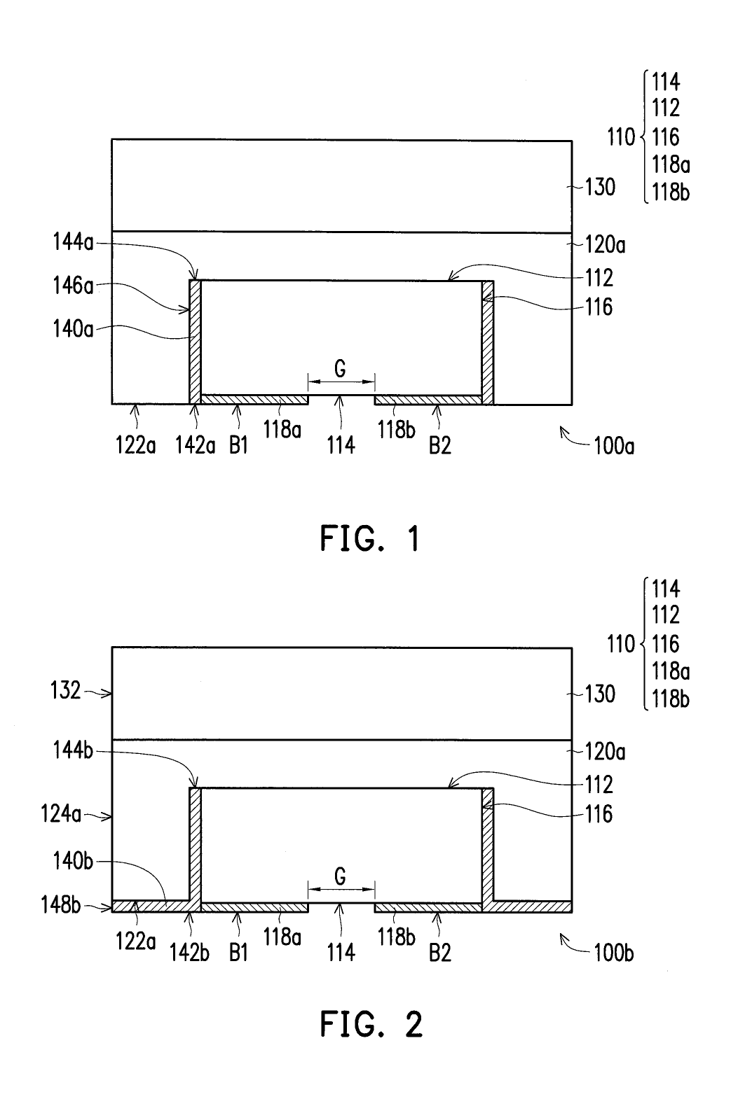

FIG. 1 is a cross-sectional schematic view illustrating a light emitting device structure according to an embodiment of the invention. With reference to FIG. 1, a light emitting device structure 100a of the present embodiment includes a light emitting device 110, a molding compound 120a, a transparent substrate 130 and a reflective layer 140a. The light emitting device 110 has an upper surface 112 and a lower surface 114 opposite to each other, a side surface 116 connecting the upper surface 112 and the lower surface 114, and a first pad 118a and a second pad 118b located on the lower surface 114 and separated from each other. The molding compound 120a at least encapsulates the upper surface 112 and the side surface 116 of the light emitting device 110, and exposes the first pad 118a and the second pad 118b of the light emitting device 110. The transparent substrate 130 is disposed above the upper surface 112 of the light emitting device 110, wherein the molding compound 120a is located between the transparent substrate 130 and the light emitting device 110. The reflective layer 140a directly covers the side surface 116 of the light emitting device 110, wherein the molding compound 120a encapsulates the reflective layer 140a and exposes a bottom surface 142a of the reflective layer 140a.

Specifically speaking, as shown in FIG. 1, the reflective layer 140a of the present embodiment directly and completely covers the side surface 116 of the light emitting device 110, and the reflective layer 140a further extends to cover peripheral surfaces of the first pad 118a and the second pad 118b. The bottom surface 142a of the reflective layer 140a is substantially aligned with a first bottom surface B1 of the first pad 118a and a second bottom surface B2 of the second pad 118b of the light emitting device 110. Here, the light emitting device 110 is realized as a light emitting diode (LED). A top surface 144a of the reflective layer 140a opposite to the bottom surface 142a is aligned with the upper surface 112 of the light emitting device 110, and a lower bottom surface 122a of the molding compound 120a is aligned with the first bottom surface B1 of the first pad 118a and the second bottom surface B2 of the second pad 118b. In other words, in the present embodiment, the first bottom surface B1 of the first pad 118a and the second bottom surface B2 of the second pad 118b of the light emitting device 110, the bottom surface 142a of the reflective layer 140a and the lower bottom surface 122a of the molding compound 120a are substantially coplanar. Namely, the above are located on the same plane. A fabricating time and costs may be reduced, and subsequent packaging or module design may be more efficient. Preferably, the reflective layer 140a of the present embodiment has a reflectivity of at least greater than 50%, wherein the reflective layer 140a is, for example, a silver layer, an aluminum layer, a Bragg reflection layer or other suitable reflective layer. However, the invention is not limited thereto.

Furthermore, the molding compound 120a of the present embodiment covers the upper surface 112 of the light emitting device 110 and a side surface 146a and the top surface 144a of the reflective layer 140a, wherein the molding compound 120a may be, for example, a transparent molding compound or a phosphor-doped molding compound. For example, in order to modify a color of light which is provided by the light emitting device 110, the phosphor-doped molding compound may be selected, wherein the phosphor is, for example, yellow fluorescent powder, red fluorescent powder, green fluorescent powder, blue fluorescent powder or yttrium aluminum garnet (YAG) fluorescent powder. These embodiments are still plausible technical solutions for the invention, and do not depart from the scope to which the invention intends to protect. In particular, the molding compound 120a of the present embodiment is further filled in a gap G between the first pad 118a and the second pad 118b of the light emitting device 110, which may isolate the first pad 118a and the second pad 118b, and protect the light emitting device 110. In addition, a material of the transparent substrate 130 of the present embodiment is, for example, glass, acrylic latex, glass phosphorous material, ceramic or sapphire. Therefore, the transparent substrate 130 may have a function of guiding light which is emitted by the light emitting device 110 and allowing the light to transmit through, and the transparent substrate 130 also strengthens the entire light emitting device structure 100a. Moreover, the transparent substrate 130 is preferably glass because its property of being easily cut makes the fabrication simpler and easier.

Since the light emitting device structure 100a of the present embodiment has the reflective layer 140a and the reflective layer 140a is directly disposed on the side surface 116 of the light emitting device 110, the reflective layer 140a may reflect a lateral light of the light emitting device 110 forward. Namely, a luminous flux of forward irradiation of the light emitting device 110 may be increased, and a luminous flux of lateral irradiation of the light emitting device 110 may be reduced. Accordingly, the light emitting device structure 100a of the present embodiment not only obtains preferable luminescent efficiency, but also minimizes color unevenness and phenomenon of yellow and blue circles, thereby providing preferable light emitting uniformity.

It has to be noted that the following embodiments use the reference numerals and parts of the contents of the aforesaid embodiment, wherein same reference numerals are adopted to represent the same or similar elements, and repetitive explanations of the same technical content are omitted. Concerning the omitted illustrations, please refer to the aforesaid embodiment. The same technical contents are not reiterated in the following embodiments.

FIG. 2 is a cross-sectional schematic view illustrating a light emitting device structure according to another embodiment of the invention. With reference to FIG. 2, a light emitting device structure 100b of the present embodiment is similar to the light emitting device structure 100a of FIG. 1. However, a primary difference between the two structures lies in that: a reflective layer 140b of the present embodiment further extends to be disposed on a lower bottom surface 122a of the molding compound 120a, and a bottom surface 142b of the reflective layer 140b is aligned with the first bottom surface B1 of the first pad 118a and the second bottom surface B2 of the second pad 118b. A top surface 144b of the reflective layer 140b opposite to the bottom surface 142b is aligned with the upper surface 112 of the light emitting device 110. A first peripheral surface 124a of the molding compound 120a is aligned with a second peripheral surface 148b of the reflective layer 140b, and the second peripheral surface 148b of the reflective layer 140b is aligned with a third peripheral surface 132 of the transparent substrate 130.

As shown in FIG. 2, the reflective layer 140b of the present embodiment extends to the lower bottom surface 122a of the molding compound 120a, and the reflective layer 140b is connected to peripheral surfaces of the first pad 118a and the second pad 118b of the light emitting device 110. Accordingly, if the reflective layer 140b is formed of a metallic material, such as a silver layer, an aluminum layer or other suitable metallic material, the reflective layer 140b may be deemed as an extension part of the first pad 118a and the second pad 118b. In other words, a contact area of electrodes in the light emitting device 110 of the present embodiment is increased with a design of the reflective layer 140b. Namely, the light emitting device 110 of the present embodiment may have a greater electrode area. Thus, when the light emitting device structure 100b is subsequently assembled to an external circuit (not shown) to form a light emitting module (not shown), alignment accuracy during assembling may also be efficiently improved.

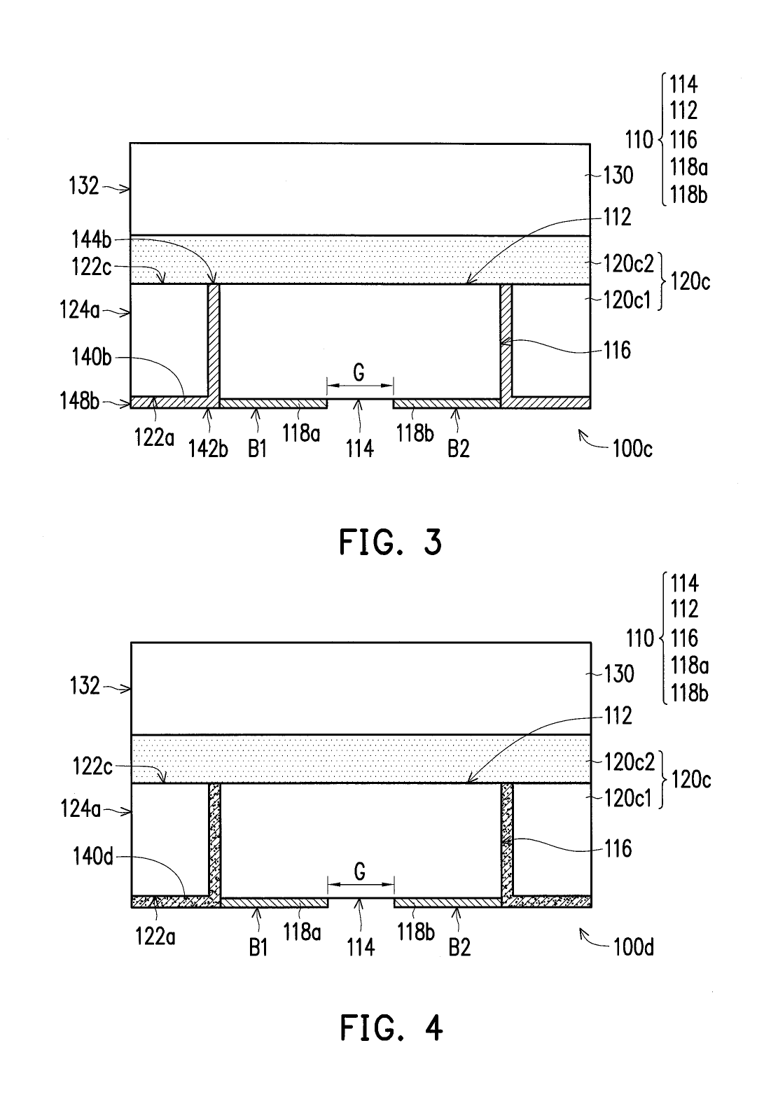

FIG. 3 is a cross-sectional schematic view illustrating a light emitting device structure according to another embodiment of the invention. With reference to FIG. 3, a light emitting device structure 100c of the present embodiment is similar to the light emitting device structure 100b of FIG. 2. A primary difference between the two structures lies in that: a molding compound 120c of the present embodiment includes a resin compound layer 120c1 and a phosphor-doped compound layer 120c2. The resin compound layer 120c1 encapsulates the reflective layer 140b, and the phosphor-doped compound layer 120c2 covers the upper surface 112 of the light emitting device 110, the top surface 144b of the reflective layer 140b and an upper top surface 122c of the resin compound layer 120c1.

Here, a material of the resin compound layer 120c1 is, for example, epoxy resin, silicone or white glue, and a purpose of the resin compound layer 120c1 is to assist in reflecting the lateral light of the light emitting device 110. Also, the phosphor-doped molding compound 120c2 is configured for modifying colors of lights emitted by the light emitting device 110, wherein the phosphor is, for example, yellow fluorescent powder, red fluorescent powder, green fluorescent powder, blue fluorescent powder or yttrium aluminum garnet (YAG) fluorescent powder. However, the invention is not limited thereto.

FIG. 4 is a cross-sectional schematic view illustrating a light emitting device structure according to another embodiment of the invention. With reference to

FIG. 4, a light emitting device structure 100d of the present embodiment is similar to the light emitting device structure 100c of FIG. 3. A primary difference between the two structures lies in that: a reflective layer 140d of the present embodiment is a reflective layer doped with a plurality of reflective particles, which obtain preferable reflection effects. In particular, these reflective particles may be formed by sputtering, bombardment, collision, implantation, embedment, diffusion or reaction, but the invention is not limited thereto.

In view of the foregoing, since the light emitting device structure of the invention has the reflective layer, and the reflective layer is directly disposed on the side surface of the light emitting device, the luminous flux of forward irradiation of the light emitting device may be increased and the luminous flux of lateral irradiation thereof may be reduced. Accordingly, the light emitting device structure of the invention not only obtains preferable luminescent efficiency, but also minimizes color unevenness and phenomenon of yellow and blue circles.

Although the invention has been disclosed with reference to the aforesaid embodiments, they are not intended to limit the invention. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting device structure, comprising:
a light emitting device having an upper surface and a lower surface opposite to each other, a side surface connecting the upper surface and the lower surface, and a first pad and a second pad located on the lower surface and separated from each other;
a molding compound at least encapsulating the upper surface and the side surface of the light emitting device, and exposing the first pad and the second pad of the light emitting device;
a transparent substrate disposed above the upper surface of the light emitting device, wherein the molding compound is located between the transparent substrate and the light emitting device; and
a reflective layer directly covering the side surface of the light emitting device, wherein the molding compound encapsulates the reflective layer and exposes a bottom surface of the reflective layer.

2. The light emitting device structure as claimed in claim 1, wherein the bottom surface of the reflective layer is aligned with a first bottom surface of the first pad and a second bottom surface of the second pad.

3. The light emitting device structure as claimed in claim 1, wherein a top surface of the reflective layer opposite to the bottom surface is aligned with the upper surface of the light emitting device.

4. The light emitting device structure as claimed in claim 1, wherein the molding compound is further filled in a gap between the first pad and the second pad of the light emitting device.

5. The light emitting device structure as claimed in claim 1, wherein the reflective layer further extends to be disposed on a lower bottom surface of the molding compound, and the bottom surface of the reflective layer is aligned with a first bottom surface of the first pad and a second bottom surface of the second pad.

6. The light emitting device structure as claimed in claim 5, wherein a first peripheral surface of the molding compound is aligned with a second peripheral surface of the reflective layer.

7. The light emitting device structure as claimed in claim 6, wherein the second peripheral surface of the reflective layer is aligned with a third peripheral surface of the transparent substrate.

8. The light emitting device structure as claimed in claim 5, wherein the molding compound comprises a resin compound layer and a phosphor-doped compound layer, the resin compound layer encapsulates the reflective layer, and the phosphor-doped compound layer covers the upper surface of the light emitting device, the top surface of the reflective layer and an upper top surface of the resin compound layer.

9. The light emitting device structure as claimed in claim 1, wherein the molding compound comprises a resin compound layer and a phosphor-doped compound layer, the resin compound layer encapsulates the reflective layer, and the phosphor-doped compound layer covers the upper surface of the light emitting device, the top surface of the reflective layer and an upper top surface of the resin compound layer.

10. The light emitting device structure as claimed in claim 1, wherein the reflective layer has a reflectivity of at least greater than 50%.

11. The light emitting device structure as claimed in claim 10, wherein the reflective layer comprises a silver layer, an aluminum layer or a is a Bragg reflection layer.

12. The light emitting device structure as claimed in claim 10, wherein the reflective layer is a reflective layer doped with a plurality of reflective particles.
